(19) United States
(12) Patent Application Publication
(10) Pub. No.: US 2024/0204745 A1
(43) Pub. Date: Jun. 20, 2024

(54) Resonator Device

(71) Applicant: SEIKO EPSON CORPORATION, Tokyo (JP)

(72) Inventor: Manabu SHIRAKI, Ina (JP)

(21) Appl. No.: 18/539,418

(22) Filed: Dec. 14, 2023

(30) Foreign Application Priority Data
Dec. 15, 2022 (JP) 2022-200021

(51) Int. Cl. H03H 9/05; H03H 9/10; H03H 9/19

(52) U.S. Cl. CPC H03H 9/0509; H03H 9/1021; H03H 9/19

(57) ABSTRACT

Provided is a resonator device in which an inner wall of a case accommodating a piezoelectric substrate includes a first inner wall and a second inner wall that intersect at a corner at which a coupling electrode is located, the piezoelectric substrate has a first surface facing a bottom surface of the case, a second surface opposite to the first surface, a first side surface facing the first inner wall, and a second side surface facing the second inner wall, an extension electrode formed at the piezoelectric substrate includes a first side surface electrode overlapping the first side surface and a second side surface electrode overlapping the second side surface, a conductive adhesive reaches the first side surface electrode and the second side surface electrode of the piezoelectric substrate from the coupling electrode formed at the case, bonds the first side surface electrode and the first inner wall, and bonds the second side surface electrode and the second inner wall.

The present application is based on, and claims priority from JP Application Serial Number 2022-200021, filed Dec. 15, 2022, the disclosure of which is hereby incorporated by reference herein in its entirety.

### BACKGROUND

### 1. Technical Field

The present disclosure relates to a resonator device.

### 2. Related Art

In the related art, a resonator device in which a resonator element is provided in a package has been known. JP-A-2000-244090 discloses a technique of installing a resonator element in a cavity of a package with a conductive adhesive. The resonator element includes an excitation electrode formed on a crystal substrate and a lead electrode extending from the excitation electrode. The lead electrode of the resonator element and a pad on a bottom surface of the package are bonded to each other with the conductive adhesive.

In response to a demand for miniaturization of a resonator device, miniaturization of a resonator element and further miniaturization of the lead electrode are also required. When the lead electrode is small, a conduction state tends to be unstable in the bonding via the conductive adhesive.

### SUMMARY

A resonator device includes: a piezoelectric substrate; an excitation electrode formed at the piezoelectric substrate; an extension electrode formed at the piezoelectric substrate and extending from the excitation electrode; a case in which the piezoelectric substrate is accommodated; a coupling electrode formed in the case; and a conductive adhesive bonding the extension electrode and the coupling electrode, in which the case has a bottom surface and an inner wall protruding from the bottom surface and surrounding the bottom surface in a frame shape, when the bottom surface is viewed in a plan view, a region of the bottom surface surrounded by the inner wall is a quadrilateral, and the coupling electrode is located at a corner of the quadrilateral, the inner wall includes a first inner wall and a second inner wall coupled to each other at the corner, the piezoelectric substrate has a first surface facing the bottom surface, a second surface opposite to the first surface, and a side surface coupling the first surface and the second surface, the side surface has a first side surface facing the first inner wall and a second side surface facing the second inner wall, the extension electrode faces the coupling electrode at the first surface and extends from the first surface to the first side surface and the second side surface, a portion of the extension electrode that overlaps the first side surface is a first side surface electrode, and a portion of the extension electrode that overlaps the second side surface is a second side surface electrode, and the conductive adhesive reaches the first side surface electrode and the second side surface electrode from the coupling electrode, bonds the first side surface electrode and the first inner wall, and bonds the second side surface electrode and the second inner wall.

### BRIEF DESCRIPTION OF THE DRAWINGS

FIG. 1 is a perspective view illustrating a resonator device.

FIG. 2 is a cross-sectional view taken along a line A-A in FIG. 1.

FIG. 3 is a plan view illustrating a case.

FIG. 4 is a plan view illustrating the case, a resonator element accommodated in the case, and a conductive adhesive.

FIG. 5 is a bottom view illustrating the resonator element.

FIG. 6 is a cross-sectional view taken along a line B-B in FIG. 4.

FIG. 7 is a cross-sectional view taken along a line C-C in FIG. 6.

FIG. 8 is a cross-sectional view taken along a line D-D in FIG. 4.

FIG. 9 is a cross-sectional view of a resonator device according to a second embodiment taken along the line A-A in FIG. 1.

FIG. 10 is a cross-sectional view taken along a line E-E in FIG. 9.

FIG. 11 is a cross-sectional view of a resonator device according to a third embodiment taken along the line A-A in FIG. 1.

FIG. 12 is a cross-sectional view of the resonator device according to the third embodiment taken along the line D-D in FIG. 4.

FIG. 13 is a cross-sectional view taken along a line F-F in FIG. 11.

FIG. 14 is a cross-sectional view of a resonator device according to a fourth embodiment taken along the line A-A in FIG. 1.

FIG. 15 is a cross-sectional view taken along a line G-G in FIG. 14.

FIG. 16 is a cross-sectional view of a resonator device according to a fifth embodiment taken along the line A-A in FIG. 1.

FIG. 17 is a cross-sectional view taken along a line H-H in FIG. 16.

### DESCRIPTION OF EMBODIMENTS

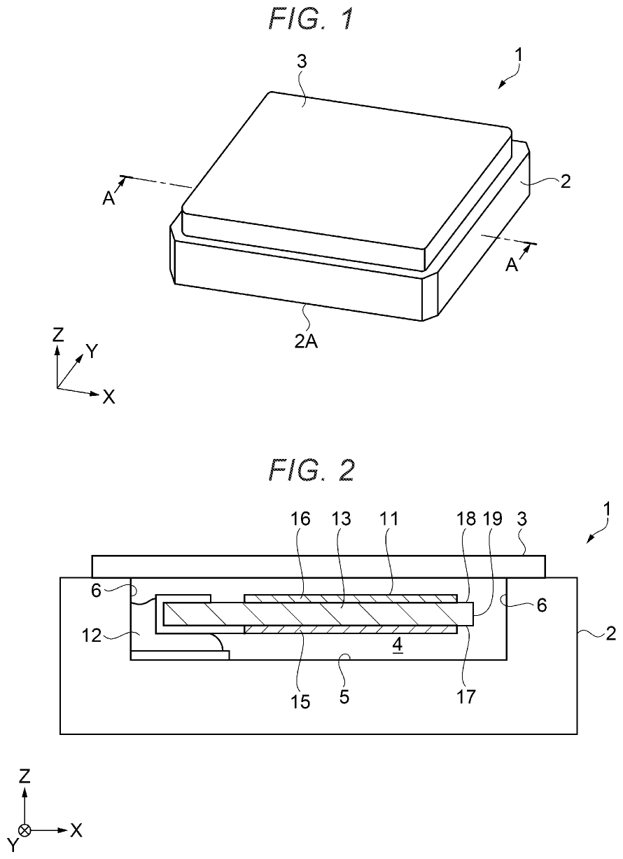

As illustrated in FIG. 1, a resonator device 1 according to an embodiment includes a case 2 and a lid 3. The lid 3 overlaps the case 2. In FIG. 1, an X axis, a Y axis, and a Z axis are added. The X axis, the Y axis, and the Z axis are coordinate axes orthogonal to one another. An X axis, a Y axis, and a Z axis are also added to drawings illustrated after FIG. 1 as necessary. In this case, the X axis, the Y axis, and the Z axis in each drawing correspond to the X axis, the Y axis, and the Z axis in FIG. 1, respectively. FIG. 1 illustrates a state in which the resonator device 1 is placed on an XY plane defined by the X axis and the Y axis. Further, in FIG. 1, an extension direction of a side 2A of the case 2 is along the X axis.

In the following description, when the X axis, the Y axis, and the Z axis are referred to in the drawings and the description describing components and units of the resonator device 1, it means that the X axis, the Y axis, and the Z axis are in a state in which the components and the units are incorporated in the resonator device 1. Arrows are given to the X axis, the Y axis, and the Z axis, respectively. In each of the X axis, the Y axis, and the Z axis, a direction of the arrow indicates a + (positive) direction, and a direction opposite to the direction of the arrow indicates a − (negative) direction. The Z axis is an axis orthogonal to the XY plane. A view when the resonator device 1 is viewed in a +Y direction is a front view.

As illustrated in FIG. 2 that is a cross-sectional view taken along a line A-A in FIG. 1, a recessed cavity 4 is formed in the case 2. The case 2 has a bottom surface 5 and an inner wall 6 protruding from the bottom surface 5. The cavity 4 is closed by the lid 3. The cavity 4 is defined by the bottom surface 5, the inner wall 6, and the lid 3.

The resonator device 1 includes a resonator element 11 and a conductive adhesive 12. The resonator element 11 includes a piezoelectric substrate 13, a first excitation electrode 15, and a second excitation electrode 16. The resonator element 11 and the conductive adhesive 12 are accommodated in the cavity 4. The piezoelectric substrate 13 has a first surface 17, a second surface 18, and a side surface 19. The first surface 17 faces the bottom surface 5 of the cavity 4. The second surface 18 is a surface opposite to the first surface 17 and faces the lid 3. The side surface 19 is a surface coupling the first surface 17 and the second surface 18.

As the piezoelectric substrate 13, a substrate of lithium niobate, lithium tantalate, or the like can be applied in addition to a crystal substrate. In the embodiment, the piezoelectric substrate 13 is an AT cut crystal substrate. The first excitation electrode 15 is formed on the first surface 17 of the piezoelectric substrate 13. The second excitation electrode 16 is formed on the second surface 18 of the piezoelectric substrate 13. The X axis, the Y axis, and the Z axis added to FIG. 1 are not related to crystal axes of a quartz crystal.

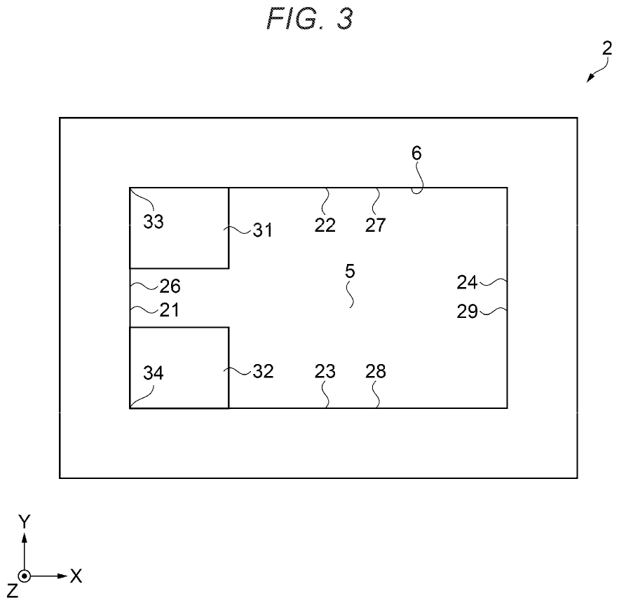

As illustrated in FIG. 3, in the case 2, a region of the bottom surface 5 surrounded by the inner wall 6 is a quadrilateral. Four sides constituting the quadrilateral include a first side 21, a second side 22, a third side 23, and a fourth side 24. As long as the quadrilateral includes the four sides including the first side 21, the second side 22, the third side 23, and the fourth side 24, the quadrilateral may include a curved line and a straight line in addition to the four sides. The first side 21 and the fourth side 24 are opposite to each other. The second side 22 and the third side 23 are opposite to each other. A portion of the inner wall 6 that corresponds to the first side 21 is a first inner wall 26. A portion of the inner wall 6 that corresponds to the second side 22 is a second inner wall 27. A portion of the inner wall 6 that corresponds to the third side 23 is a third inner wall 28. A portion of the inner wall 6 that corresponds to the fourth side 24 is a fourth inner wall 29. The case 2 is implemented by a ceramic substrate.

A first pad electrode 31 and a second pad electrode 32 are formed on the bottom surface 5 of the case 2. The first pad electrode 31 and the second pad electrode 32 are arranged along the first side 21 with a gap therebetween. The first pad electrode 31 is located at a corner 33 of the quadrilateral. The corner 33 is a portion where the first inner wall 26 and the second inner wall 27 are coupled. The first inner wall 26 and the second inner wall 27 are coupled to each other at the corner 33. The coupling between the first inner wall 26 and the second inner wall 27 includes both a case where the first inner wall 26 and the second inner wall 27 are in direct contact with each other and a case where the first inner wall 26 and the second inner wall 27 are coupled to each other via another curved surface, another flat surface, or the like. The first pad electrode 31 is an example of a coupling electrode.

The second pad electrode 32 is located at a corner 34 of the quadrilateral. The corner 34 is a portion where the first inner wall 26 and the third inner wall 28 are coupled. The first inner wall 26 and the third inner wall 28 are coupled to each other at the corner 34. The coupling between the first inner wall 26 and the third inner wall 28 includes both a case where the first inner wall 26 and the third inner wall 28 are in direct contact with each other and a case where the first inner wall 26 and the third inner wall 28 are coupled to each other via another curved surface, another flat surface, or the like.

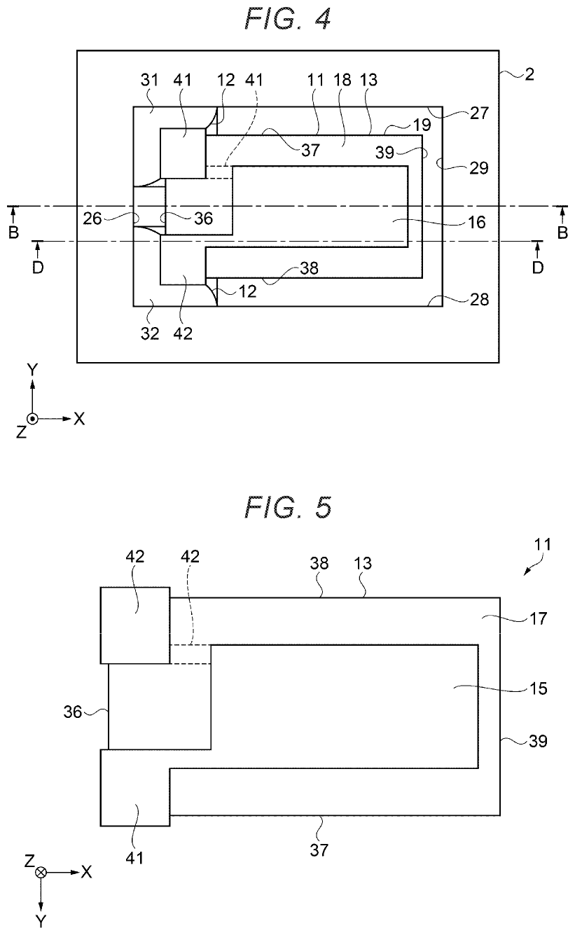

As illustrated in FIG. 4, the piezoelectric substrate 13 of the resonator element 11 includes a first side surface 36, a second side surface 37, a third side surface 38, and a fourth side surface 39. The first side surface 36 faces the first inner wall 26 of the case 2. The second side surface 37 faces the second inner wall 27 of the case 2. The third side surface 38 faces the third inner wall 28 of the case 2. The fourth side surface 39 faces the fourth inner wall 29 of the case 2. The first side surface 36, the second side surface 37, the third side surface 38, and the fourth side surface 39 constitute the side surface 19 of the piezoelectric substrate 13. The first side surface 36, the second side surface 37, the third side surface 38, and the fourth side surface 39 are portions different from one another. The first side surface 36 and the fourth side surface 39 face opposite directions. The second side surface 37 and the third side surface 38 face opposite directions.

FIG. 5 is a bottom view illustrating the resonator element 11. The bottom view of the resonator element 11 is a view of the resonator element 11 viewed in a +Z direction. The +Z direction is a direction from the first surface 17 to the second surface 18 of the piezoelectric substrate 13. That is, the bottom view of the resonator element 11 is a view of the resonator element 11 viewed in a direction facing the first surface 17 of the piezoelectric substrate 13. As illustrated in FIG. 5, the first excitation electrode 15 is formed in a region inside an outer edge of the first surface 17. In the resonator element 11, a first lead electrode 41 extends from the first excitation electrode 15. The first lead electrode 41 is formed on the piezoelectric substrate 13. The first excitation electrode 15 and the first lead electrode 41 are continuous. The first lead electrode 41 is an example of an extension electrode.

The first lead electrode 41 reaches a part of the first side surface 36 of the piezoelectric substrate 13 and a part of the second side surface 37 of the piezoelectric substrate 13. The first lead electrode 41 extends from the first excitation electrode 15 to the first side surface 36 and the second side surface 37. As illustrated in FIG. 4, the first lead electrode 41 extending to a part of the first side surface 36 and a part of the second side surface 37 further extends to the second surface 18. The first lead electrode 41 covers a part of the first side surface 36 of the piezoelectric substrate 13 and a part of the second side surface 37 of the piezoelectric substrate 13. The first lead electrode 41 extending from the first excitation electrode 15 located on the first surface 17 reaches the second surface 18 via the first side surface 36 and the second side surface 37.

As illustrated in FIG. 4, the second excitation electrode 16 is formed in a region inside an outer edge of the second surface 18. In the resonator element 11, a second lead electrode 42 extends from the second excitation electrode 16. The second lead electrode 42 is formed at the piezoelectric substrate 13. The second excitation electrode 16 and the second lead electrode 42 are continuous. The second lead electrode 42 reaches a part of the first side surface 36 of the piezoelectric substrate 13 and a part of the third side surface 38 of the piezoelectric substrate 13. The second lead electrode 42 extends from the second excitation electrode 16 to the first side surface 36 and the third side surface 38. As illustrated in FIG. 5, the second lead electrode 42 extending to a part of the first side surface 36 and a part of the third side surface 38 further extends to the first surface 17. The second lead electrode 42 covers a part of the first side surface 36 of the piezoelectric substrate 13 and a part of the third side surface 38 of the piezoelectric substrate 13. The second lead electrode 42 extending from the second excitation electrode 16 located on the second surface 18 reaches the first surface 17 via the first side surface 36 and the third side surface 38.

In the embodiment, a pattern of the first excitation electrode 15 and the first lead electrode 41 in the bottom view of FIG. 5 is the same as a pattern of the second excitation electrode 16 and the second lead electrode 42 in a plan view of FIG. 4. That is, electrode layers having the same pattern are formed on both the first surface 17 and the second surface 18. Therefore, the resonator element 11 can be mounted on the case 2 without distinguishing front and back sides of the resonator element 11. The first excitation electrode 15 and the second excitation electrode 16 overlap each other.

As illustrated in FIG. 4, a part of the first side surface 36 and a part of the second side surface 37 of the piezoelectric substrate 13 are located in a region of the first pad electrode 31 in the plan view. A part of the first side surface 36 and a part of the third side surface 38 of the piezoelectric substrate 13 are located in a region of the second pad electrode 32 in the plan view. The first lead electrode 41 overlaps the region of the first pad electrode 31 in the plan view. The first lead electrode 41 reaches the first side surface 36 and the second side surface 37 from the second surface 18 of the piezoelectric substrate 13 in a region overlapping the first pad electrode 31 in the plan view. The second lead electrode 42 overlaps the region of the second pad electrode 32 in the plan view. The second lead electrode 42 reaches the first side surface 36 and the third side surface 38 from the second surface 18 of the piezoelectric substrate 13 in a region overlapping the second pad electrode 32 in the plan view.

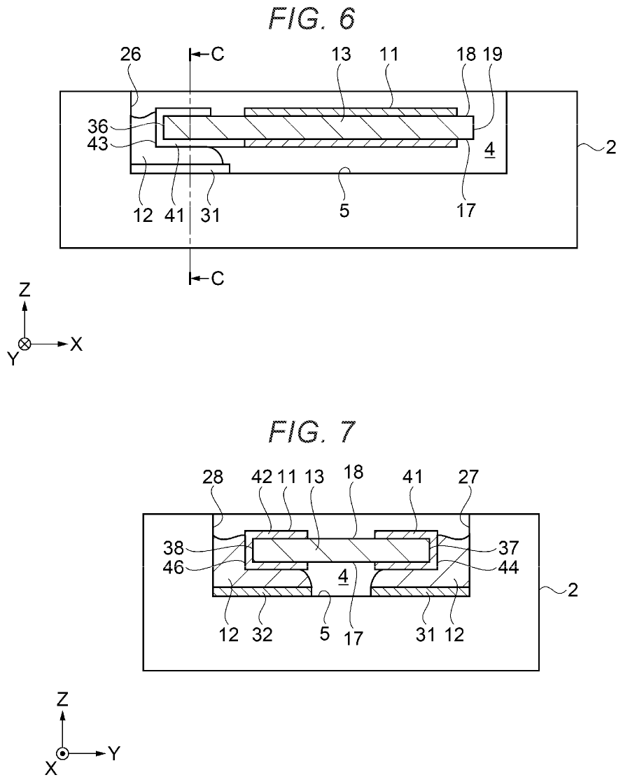

The first lead electrode 41 extends from the second surface 18 through the first side surface 36 and the second side surface 37 to the first surface 17 in the region overlapping the first pad electrode 31. Accordingly, as illustrated in FIG. 6 that is a cross-sectional view taken along a line B-B in FIG. 4, the first lead electrode 41 on the first surface 17 faces the first pad electrode 31. A part of the first lead electrode 41 overlapping the first side surface 36 is defined as a first side portion electrode 43. The first side portion electrode 43 is an example of a first side surface electrode. The conductive adhesive 12 bonds the first pad electrode 31 and the first lead electrode 41. The conductive adhesive 12 reaches the first side portion electrode 43 from the first pad electrode 31. Further, the conductive adhesive 12 bonds the first side portion electrode 43 and the first inner wall 26. A position of the line A-A in FIG. 1 is the same as a position of the line B-B in FIG. 4. That is, FIG. 6 corresponds to a view in which the lid 3 illustrated in FIG. 2 is omitted.

As illustrated in FIG. 7 that is a cross-sectional view taken along a line C-C in FIG. 6, the first lead electrode 41 extends from the second surface 18 through the second side surface 37 to the first surface 17 in the region overlapping the first pad electrode 31. A portion of the first lead electrode 41 that overlaps the second side surface 37 is defined as a second side portion electrode 44. The second side portion electrode 44 is an example of a second side surface electrode. The conductive adhesive 12 reaches the second side portion electrode 44 from the first pad electrode 31. Further, the conductive adhesive 12 bonds the second side portion electrode 44 and the second inner wall 27. Various methods can be applied to install the resonator element 11 in the case 2. For example, a method of disposing the resonator element 11 in the case 2 in a state in which the conductive adhesive 12 is applied to the first pad electrode 31 and the second pad electrode 32 of the case 2 can be applied.

FIGS. 6 and 7 illustrate the first side surface 36 and the second side surface 37 as flat surfaces, but the first side surface 36 and the second side surface 37 are not limited to flat surfaces. The first side surface 36 and the second side surface 37 may be curved surfaces or may have a plurality of flat surfaces. In the resonator device 1, the first lead electrode 41 extends from the first surface 17 facing the first pad electrode 31 to the first side surface 36 and the second side surface 37. The conductive adhesive 12 bonding the first lead electrode 41 and the first pad electrode 31 reaches the first side portion electrode 43 on the first side surface 36 and the second side portion electrode 44 on the second side surface 37 from the first pad electrode 31. Accordingly, since a contact area between the conductive adhesive 12 and the first lead electrode 41 is increased, conduction between the first lead electrode 41 and the conductive adhesive 12 can be enhanced. Accordingly, a conduction state between the first lead electrode 41 and the conductive adhesive 12 is easily stabilized. Further, the conductive adhesive 12 bonds the first side portion electrode 43 and the first inner wall 26, and bonds the second side portion electrode 44 and the second inner wall 27. Therefore, a bonding strength between the case 2 and the first lead electrode 41 can be increased.

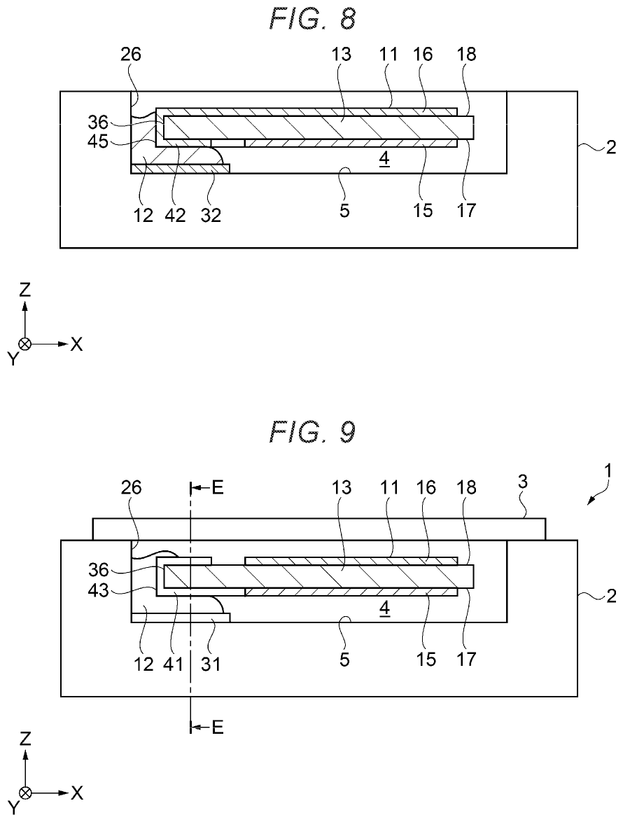

As described above, the second lead electrode 42 extends from the second surface 18 through the first side surface 36 and the third side surface 38 to the first surface 17 in the region overlapping the second pad electrode 32. Accordingly, as illustrated in FIG. 8 that is a cross-sectional view taken along a line D-D in FIG. 4, the second lead electrode 42 on the first surface 17 faces the second pad electrode 32. A portion of the second lead electrode 42 that overlaps the first side surface 36 is defined as a third side portion electrode 45. The conductive adhesive 12 bonds the second pad electrode 32 and the second lead electrode 42. The conductive adhesive 12 reaches the third side portion electrode 45 from the second pad electrode 32. Further, the conductive adhesive 12 bonds the third side portion electrode 45 and the first inner wall 26.

As illustrated in FIG. 7, the second lead electrode 42 extends from the second surface 18 through the third side surface 38 to the first surface 17 in the region overlapping the second pad electrode 32. A portion of the second lead electrode 42 that overlaps the third side surface 38 is defined as a fourth side portion electrode 46. The conductive adhesive 12 reaches the fourth side portion electrode 46 from the second pad electrode 32. Further, the conductive adhesive 12 bonds the fourth side portion electrode 46 and the third inner wall 28. FIG. 7 illustrates the third side surface 38 as a flat surface, but the third side surface 38 is not limited to a flat surface. The third side surface 38 may be a curved surface or may have a plurality of flat surfaces.

In the resonator device 1, the second lead electrode 42 extends from the first surface 17 facing the second pad electrode 32 to the first side surface 36 and the third side surface 38. The conductive adhesive 12 bonding the second lead electrode 42 and the second pad electrode 32 reaches the third side portion electrode 45 on the first side surface 36 and the fourth side portion electrode 46 on the third side surface 38 from the second pad electrode 32. Accordingly, since a contact area between the conductive adhesive 12 and the second lead electrode 42 is increased, conduction between the second lead electrode 42 and the conductive adhesive 12 can be enhanced. Accordingly, a conduction state between the second lead electrode 42 and the conductive adhesive 12 is easily stabilized. Furthermore, the conductive adhesive 12 bonds the third side portion electrode 45 and the first inner wall 26, and bonds the fourth side portion electrode 46 and the third inner wall 28. Therefore, a bonding strength between the case 2 and the second lead electrode 42 can be increased.

In the resonator device 1, the conduction state between the first lead electrode 41 and the conductive adhesive 12 is easily stabilized, and the conduction state between the second lead electrode 42 and the conductive adhesive 12 is also easily stabilized. As a result, in the resonator device 1, it is possible to increase reliability related to electrical coupling between the resonator element 11 and the first pad electrode 31 and electrical coupling between the resonator element 11 and the second pad electrode 32. Further, the conductive adhesive 12 bonds the first side portion electrode 43 and the first inner wall 26, and bonds the second side portion electrode 44 and the second inner wall 27. In the resonator device 1, the bonding strength between the case 2 and the first lead electrode 41 can be increased, and the bonding strength between the case 2 and the second lead electrode 42 can be increased. Therefore, since a bonding strength between the case 2 and the resonator element 11 is increased, reliability of the resonator device 1 can be increased.

The embodiment described above is a first embodiment, and hereinafter, a second embodiment will be described.

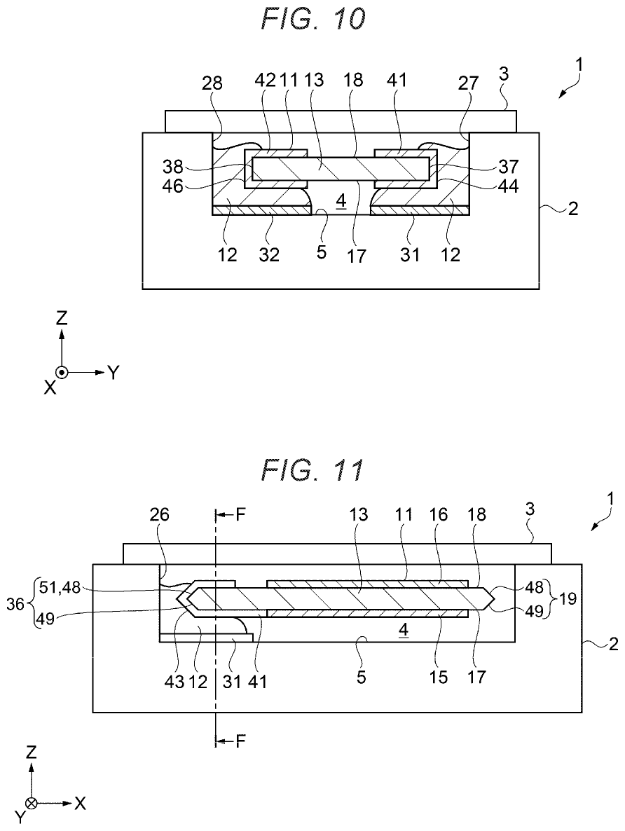

In contrast to the first embodiment, a configuration in which the conductive adhesive 12 extends to the first lead electrode 41 located on the second surface 18 can be adopted. The configuration in which the conductive adhesive 12 extends to the first lead electrode 41 located on the second surface 18 will be described as the second embodiment. FIG. 9 is a cross-sectional view of the resonator device 1 according to the second embodiment taken along the line A-A in FIG. 1. In the second embodiment, as illustrated in FIG. 9, the conductive adhesive 12 extends from the first side portion electrode 43 to the first lead electrode 41 located on the second surface 18. Further, in the second embodiment, as illustrated in FIG. 10 that is a cross-sectional view taken along a line E-E in FIG. 9, the conductive adhesive 12 extends from the second side portion electrode 44 to the first lead electrode 41 located on the second surface 18.

According to the second embodiment, the conductive adhesive 12 bonding the first pad electrode 31 and the first lead electrode 41 reaches the first lead electrode 41 located on the second surface 18 from the first side portion electrode 43 and the second side portion electrode 44. Accordingly, compared to the first embodiment, since the contact area between the conductive adhesive 12 and the first lead electrode 41 is increased, the conduction between the first lead electrode 41 and the conductive adhesive 12 can be further enhanced. Accordingly, the conduction state between the first lead electrode 41 and the conductive adhesive 12 is more easily stabilized. The conductive adhesive 12 wraps around from the first surface 17 to the second surface 18 through the first side portion electrode 43 and the second side portion electrode 44. Therefore, compared to the first embodiment, a bonding strength between the first pad electrode 31 and the first lead electrode 41 is more easily increased.

In the second embodiment, the conductive adhesive 12 extends from the third side portion electrode 45 to the second lead electrode 42 located on the second surface 18. Further, in the second embodiment, as illustrated in FIG. 10, the conductive adhesive 12 extends from the fourth side portion electrode 46 to the second lead electrode 42 located on the second surface 18. Therefore, the conductive adhesive 12 bonding the second pad electrode 32 and the second lead electrode 42 reaches the second lead electrode 42 located on the second surface 18 from the third side portion electrode 45 and the fourth side portion electrode 46. Accordingly, compared to the first embodiment, since the contact area between the conductive adhesive 12 and the second lead electrode 42 is increased, the conduction between the second lead electrode 42 and the conductive adhesive 12 can be further enhanced. Accordingly, the conduction state between the second lead electrode 42 and the conductive adhesive 12 is more easily stabilized. The conductive adhesive 12 wraps around from the first surface 17 to the second surface 18 through the third side portion electrode 45 and the fourth side portion electrode 46. Therefore, compared to the first embodiment, a bonding strength between the second pad electrode 32 and the second lead electrode 42 is more easily increased.

In the resonator device 1 according to the second embodiment, the conduction state between the first lead electrode 41 and the conductive adhesive 12 is more easily stabilized, and the conduction state between the second lead electrode 42 and the conductive adhesive 12 is also more easily stabilized. As a result, in the second embodiment, it is possible to further increase the reliability related to the electrical coupling between the resonator element 11 and the first pad electrode 31 and the electrical coupling between the resonator element 11 and the second pad electrode 32. Further, since the conductive adhesive 12 wraps around from the first surface 17 to the second surface 18 through the side surface 19, the bonding strength between the case 2 and the resonator element 11 is further increased. As a result, the reliability of the resonator device 1 can be further increased.

A third embodiment will be described.

The resonator device 1 according to the third embodiment has the same configuration as the resonator device 1 according to the first embodiment except that a shape of the side surface 19 of the piezoelectric substrate 13 is different. In the following description, components according to the third embodiment that are the same as those according to the first embodiment are denoted by the same reference numerals as those according to the first embodiment, and detailed description thereof will be omitted.

FIG. 11 is a cross-sectional view of the resonator device 1 according to the third embodiment taken along the line A-A in FIG. 1. In the third embodiment, the side surface 19 of the piezoelectric substrate 13 includes an upper inclined surface 48 and a lower inclined surface 49. The upper inclined surface 48 and the lower inclined surface 49 are inclined with respect to the first surface 17. The upper inclined surface 48 and the lower inclined surface 49 are formed by, for example, etching a crystal substrate. In the embodiment, the upper inclined surface 48 and the lower inclined surface 49 can be formed when an outer shape of the piezoelectric substrate 13 is cut out by etching the crystal substrate. A portion of the upper inclined surface 48 that is located on the first side surface 36 is defined as a first upper inclined surface 51. The first upper inclined surface 51 is an example of a first inclined surface.

The first upper inclined surface 51 is inclined in a direction in which a vertical distance from the first surface 17 decreases toward the first inner wall 26. That is, the first upper inclined surface 51 is inclined in a direction toward a −Z direction and a −X direction. In the first side surface 36, the lower inclined surface 49 is inclined toward the +Z direction and the −X direction. The conductive adhesive 12 reaches a portion of the first side portion electrode 43 of the first lead electrode 41 that is located on the first upper inclined surface 51. Further, the conductive adhesive 12 bonds the first side portion electrode 43 and the first inner wall 26.

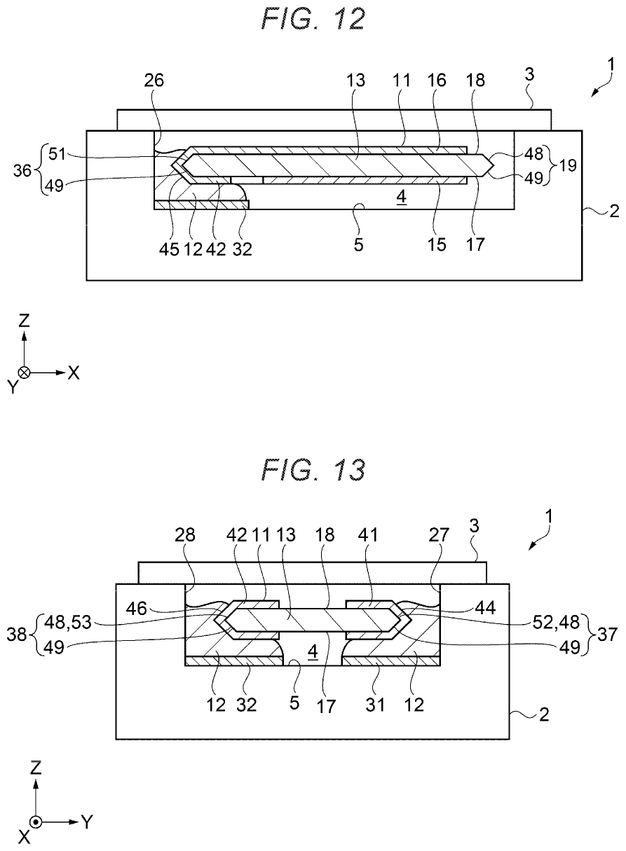

FIG. 12 is a cross-sectional view of the resonator device 1 according to the third embodiment taken along the line D-D in FIG. 4. The conductive adhesive 12 reaches a portion of the third side portion electrode 45 of the second lead electrode 42 that is located on the first upper inclined surface 51. Further, the conductive adhesive 12 bonds the third side portion electrode 45 and the first inner wall 26.

As illustrated in FIG. 13 that is a cross-sectional view taken along a line F-F in FIG. 11, a portion of the upper inclined surface 48 that is located on the second side surface 37 is defined as a second upper inclined surface 52. The second upper inclined surface 52 is an example of a second inclined surface. The second upper inclined surface 52 is inclined in a direction in which a vertical distance from the first surface 17 decreases toward the second inner wall 27. That is, the second upper inclined surface 52 is inclined in the −Z direction toward a +Y direction. In the second side surface 37, the lower inclined surface 49 is inclined in the +Z direction toward the +Y direction. The conductive adhesive 12 reaches a portion of the second side portion electrode 44 of the first lead electrode 41 that is located on the second upper inclined surface 52. Further, the conductive adhesive 12 bonds the second side portion electrode 44 and the second inner wall 27.

In the third embodiment, since the conductive adhesive 12 has a shape wrapping around from the first surface 17 to the first upper inclined surface 51 and the second upper inclined surface 52, a bonding strength between the piezoelectric substrate 13 and the case 2 is more easily increased than in the first embodiment. Further, in the third embodiment, an area of the first side portion electrode 43 and an area of the second side portion electrode 44 can be made larger than those in the first embodiment by the upper inclined surface 48 and the lower inclined surface 49. Therefore, compared to the first embodiment, since the contact area between the conductive adhesive 12 and the first lead electrode 41 is increased, the conduction between the first lead electrode 41 and the conductive adhesive 12 can be enhanced. Accordingly, the conduction state between the first lead electrode 41 and the conductive adhesive 12 is more easily stabilized.

A portion of the upper inclined surface 48 that is located on the third side surface 38 is defined as a third upper inclined surface 53. The third upper inclined surface 53 is inclined in a direction in which a vertical distance from the first surface 17 decreases toward the third inner wall 28. That is, the third upper inclined surface 53 is inclined in the −Z direction toward a −Y direction. In the third side surface 38, the lower inclined surface 49 is inclined in the +Z direction toward the −Y direction. The conductive adhesive 12 reaches a portion of the fourth side portion electrode 46 of the second lead electrode 42 that is located on the third upper inclined surface 53. Further, the conductive adhesive 12 bonds the fourth side portion electrode 46 and the third inner wall 28.

In the third embodiment, since the conductive adhesive 12 has a shape wrapping around from the first surface 17 to the first upper inclined surface 51 and the third upper inclined surface 53, the bonding strength between the piezoelectric substrate 13 and the case 2 is more easily increased than in the first embodiment. Further, in the third embodiment, an area of the third side portion electrode 45 and an area of the fourth side portion electrode 46 can be made larger than those in the first embodiment by the upper inclined surface 48 and the lower inclined surface 49. Therefore, compared to the first embodiment, since the contact area between the conductive adhesive 12 and the second lead electrode 42 is increased, the conduction between the second lead electrode 42 and the conductive adhesive 12 can be enhanced. Accordingly, the conduction state between the second lead electrode 42 and the conductive adhesive 12 is more easily stabilized.

In the third embodiment, the conductive adhesive 12 has a shape wrapping around from the first surface 17 to the first upper inclined surface 51 and the second upper inclined surface 52, and the conductive adhesive 12 has a shape wrapping around from the first surface 17 to the first upper inclined surface 51 and the third upper inclined surface 53. Accordingly, in the third embodiment, the bonding strength between the piezoelectric substrate 13 and the case 2 is more easily increased than in the first embodiment. Further, in the third embodiment, the area of the first side portion electrode 43 and the area of the second side portion electrode 44 can be made larger than those in the first embodiment by the upper inclined surface 48 and the lower inclined surface 49. In addition, in the third embodiment, the area of the third side portion electrode 45 and the area of the fourth side portion electrode 46 can be made larger than those in the first embodiment by the upper inclined surface 48 and the lower inclined surface 49. Therefore, the contact area between the conductive adhesive 12 and the first lead electrode 41 is further increased and the contact area between the conductive adhesive 12 and the second lead electrode 42 is further increased as compared with the first embodiment. Accordingly, in the third embodiment, compared to the first embodiment, the conduction state between the first lead electrode 41 and the conductive adhesive 12 can be more easily stabilized. Further, in the third embodiment, compared to the first embodiment, the conduction state between the second lead electrode 42 and the conductive adhesive 12 can be more easily stabilized. As a result, in the third embodiment, it is possible to further increase the reliability related to the electrical coupling between the resonator element 11 and the first pad electrode 31 and the electrical coupling between the resonator element 11 and the second pad electrode 32.

A fourth embodiment will be described.

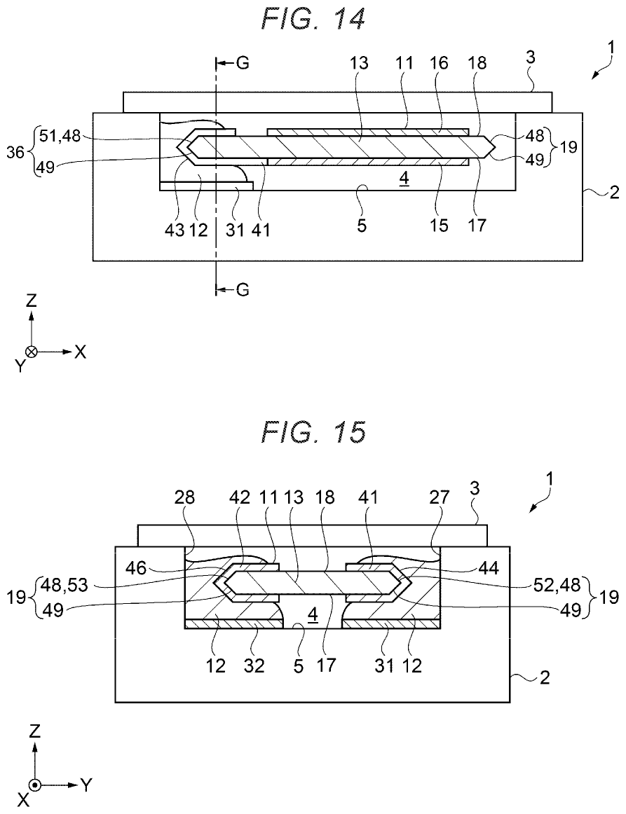

In contrast to the third embodiment, a configuration in which the conductive adhesive 12 extends to the first lead electrode 41 located on the second surface 18 can be adopted. The configuration in which the conductive adhesive 12 extends to the first lead electrode 41 located on the second surface 18 will be described as the fourth embodiment. FIG. 14 is a cross-sectional view of the resonator device 1 according to the fourth embodiment taken along the line A-A in FIG. 1. In the fourth embodiment, as illustrated in FIG. 14, the conductive adhesive 12 extends from the first side portion electrode 43 to the first lead electrode 41 located on the second surface 18. Further, in the fourth embodiment, as illustrated in FIG. 15 which is a cross-sectional view taken along a line G-G in FIG. 14, the conductive adhesive 12 extends from the second side portion electrode 44 to the first lead electrode 41 located on the second surface 18.

According to the fourth embodiment, the conductive adhesive 12 bonding the first pad electrode 31 and the first lead electrode 41 reaches the first lead electrode 41 located on the second surface 18 from the first side portion electrode 43 and the second side portion electrode 44. Accordingly, compared to the third embodiment, since the contact area between the conductive adhesive 12 and the first lead electrode 41 is increased, the conduction between the first lead electrode 41 and the conductive adhesive 12 can be further enhanced. Accordingly, the conduction state between the first lead electrode 41 and the conductive adhesive 12 is more easily stabilized. The conductive adhesive 12 wraps around from the first surface 17 to the second surface 18 through the first side portion electrode 43 and the second side portion electrode 44. Therefore, compared to the third embodiment, the bonding strength between the first pad electrode 31 and the first lead electrode 41 is more easily increased.

In the fourth embodiment, the conductive adhesive 12 extends from the third side portion electrode 45 to the second lead electrode 42 located on the second surface 18. Further, in the fourth embodiment, as illustrated in FIG. 15, the conductive adhesive 12 extends from the fourth side portion electrode 46 to the second lead electrode 42 located on the second surface 18. Therefore, the conductive adhesive 12 bonding the second pad electrode 32 and the second lead electrode 42 reaches the second lead electrode 42 located on the second surface 18 from the third side portion electrode 45 and the fourth side portion electrode 46. Accordingly, compared to the third embodiment, since the contact area between the conductive adhesive 12 and the second lead electrode 42 is increased, the conduction between the second lead electrode 42 and the conductive adhesive 12 can be further enhanced. Accordingly, the conduction state between the second lead electrode 42 and the conductive adhesive 12 is more easily stabilized. The conductive adhesive 12 wraps around from the first surface 17 to the second surface 18 through the third side portion electrode 45 and the fourth side portion electrode 46. Therefore, compared to the third embodiment, the bonding strength between the second pad electrode 32 and the second lead electrode 42 is more easily increased.

In the resonator device 1 according to the fourth embodiment, compared to the third embodiment, the conduction state between the first lead electrode 41 and the conductive adhesive 12 is more easily stabilized, and the conduction state between the second lead electrode 42 and the conductive adhesive 12 is also more easily stabilized. As a result, in the fourth embodiment, it is possible to further increase the reliability related to the electrical coupling between the resonator element 11 and the first pad electrode 31 and the electrical coupling between the resonator element 11 and the second pad electrode 32. Further, since the conductive adhesive 12 wraps around from the first surface 17 to the second surface 18 through the side surface 19, the bonding strength between the case 2 and the resonator element 11 is further increased compared to the third embodiment. As a result, the reliability of the resonator device 1 can be further increased.

A fifth embodiment will be described.

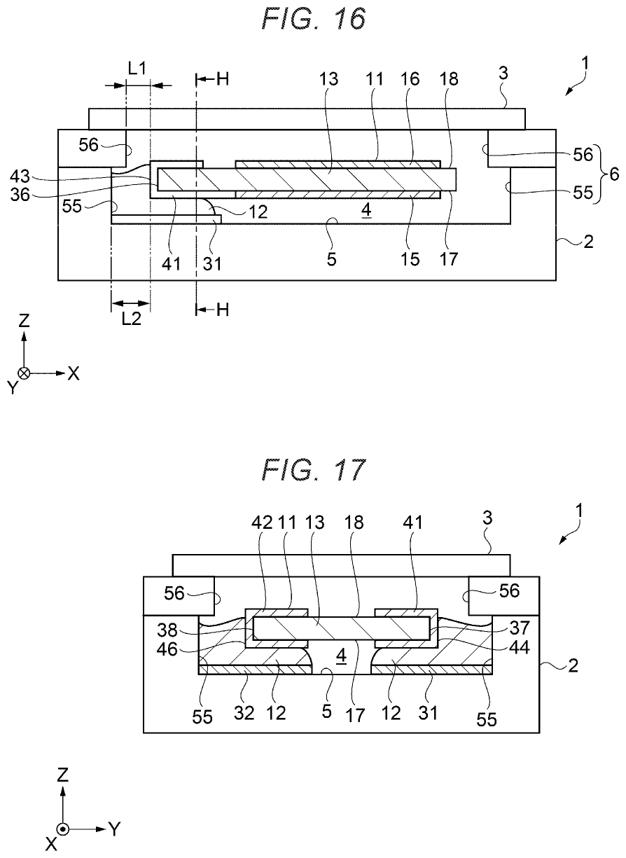

FIG. 16 is a cross-sectional view of the resonator device 1 according to the fifth embodiment taken along the line A-A in FIG. 1. In the fifth embodiment, as illustrated in FIG. 16, the inner wall 6 of the case 2 includes a first portion 55 and a second portion 56. The fifth embodiment has the same configuration as each of the first embodiment to the fourth embodiment except that the inner wall 6 of the case 2 includes the first portion 55 and the second portion 56. Therefore, components according to the fifth embodiment that are the same as those according to the first embodiment to the fourth embodiment are denoted by the same reference numerals as those according to the first embodiment to the fourth embodiment, and detailed description thereof will be omitted.

The first portion 55 protrudes from the bottom surface 5. The second portion 56 is located on an opposite side of the first portion 55 from the bottom surface 5. The second portion 56 is located in the +Z direction relative to the first portion 55. When viewing a cross-section of the case 2 taken along a plane orthogonal to the bottom surface 5, a distance L1 between the second portion 56 and the piezoelectric substrate 13 is less than a distance L2 between the first portion 55 and the piezoelectric substrate 13 at a distance parallel to the bottom surface 5. That is, the second portion 56 of the inner wall 6 protrudes inward relative to the first portion 55. Therefore, a step is generated between the first portion 55 and the second portion 56. The second portion 56 is formed in an annular shape when viewing the case 2 in the plan view. In the plan view, the second portion 56 annularly surrounds the resonator element 11. A portion of the case 2 that protrudes inward relative to the first portion 55 is also defined as a protruding portion. The inner wall 6 of the protruding portion is the second portion 56.

As illustrated in FIG. 17 that is a cross-sectional view taken along a line H-H in FIG. 16, the second portion 56 is located on an opposite side of the first pad electrode 31 and the second pad electrode 32 from the bottom surface 5. In other words, protrusion amounts of the first pad electrode 31 and the second pad electrode 32 with respect to the bottom surface 5 are less than a protrusion amount of the first portion 55 with respect to the bottom surface 5. Accordingly, a gap is ensured between the first pad electrode 31 and the second portion 56. Similarly, a gap is ensured between the second pad electrode 32 and the second portion 56. With the configuration described above, in the fifth embodiment, the conductive adhesive 12 is easily prevented from spreading from the first portion 55 to the second portion 56 due to the step between the first portion 55 and the second portion 56.

For example, when the lid 3 is formed of a metal, when the conductive adhesive 12 comes into contact with the lid 3 along the inner wall 6, the resonator element 11 and the lid 3 are electrically short-circuited. According to the fifth embodiment, the conductive adhesive 12 is easily prevented from reaching the lid 3 along the inner wall 6. Accordingly, the reliability of the resonator device 1 is easily increased.

In the first embodiment to the fifth embodiment, a name of the second inner wall 27 and a name of the third inner wall 28 may be exchanged. Accordingly, a name of the second side surface 37 and a name of the third side surface 38 of the piezoelectric substrate 13 are exchanged with each other, and a name of the first side portion electrode 43 and a name of the third side portion electrode 45 are exchanged with each other. Further, a name of the second side portion electrode 44 and a name of the fourth side portion electrode 46 are exchanged with each other. In this case, the second lead electrode 42 corresponds to the extension electrode, and the second pad electrode 32 corresponds to the coupling electrode.

What is claimed is:

1. A resonator device comprising:
a piezoelectric substrate;
an excitation electrode formed at the piezoelectric substrate;
an extension electrode formed at the piezoelectric substrate and extending from the excitation electrode;
a case in which the piezoelectric substrate is accommodated;
a coupling electrode formed in the case; and
a conductive adhesive bonding the extension electrode and the coupling electrode, wherein
the case has a bottom surface and an inner wall protruding from the bottom surface and surrounding the bottom surface in a frame shape,
when the bottom surface is viewed in a plan view, a region of the bottom surface surrounded by the inner wall is a quadrilateral, and the coupling electrode is located at a corner of the quadrilateral,
the inner wall includes a first inner wall and a second inner wall coupled to each other at the corner,
the piezoelectric substrate has a first surface facing the bottom surface, a second surface opposite to the first surface, and a side surface coupling the first surface and the second surface,
the side surface has a first side surface facing the first inner wall and a second side surface facing the second inner wall,
the extension electrode faces the coupling electrode at the first surface and extends from the first surface to the first side surface and the second side surface,
a portion of the extension electrode that overlaps the first side surface is a first side surface electrode, and a portion of the extension electrode that overlaps the second side surface is a second side surface electrode, and
the conductive adhesive reaches the first side surface electrode and the second side surface electrode from the coupling electrode, bonds the first side surface electrode and the first inner wall, and bonds the second side surface electrode and the second inner wall.

2. The resonator device according to claim 1, wherein
the first side surface and the second side surface respectively include a first inclined surface and a second inclined surface that are inclined with respect to the first surface,
the first inclined surface is inclined in a direction in which a vertical distance from the first surface decreases toward the first inner wall,
the second inclined surface is inclined in a direction in which a vertical distance from the first surface decreases toward the second inner wall, and
the conductive adhesive reaches the first side surface electrode located at the first inclined surface and the second side surface electrode located at the second inclined surface.

3. The resonator device according to claim 1, wherein
the extension electrode extends from each of the first side surface electrode and the second side surface electrode to the second surface, and
the conductive adhesive reaches the extension electrode located at the second surface from each of the first side surface electrode and the second side surface electrode.

4. The resonator device according to claim 1, wherein
the inner wall includes a first portion protruding from the bottom surface and a second portion located on an opposite side of the first portion from the bottom surface,
when viewing a cross-section of the case taken along a plane orthogonal to the bottom surface, a distance between the second portion and the piezoelectric substrate is less than a distance between the first portion and the piezoelectric substrate at a distance parallel to the bottom surface, and
the second portion is located on an opposite side of the coupling electrode from the bottom surface.
